(19) United States
(12) Patent Application Publication
(10) Pub. No.: US 2017/0285573 A1
(43) Pub. Date: Oct. 5, 2017

(54) Crystalline Compounds for Use in Mechanical Watches and Methods of Manufacture Thereof

(71) Applicant: Firehouse Horology, Inc., New York, NY (US)

(72) Inventors: Nicholas Manousos, Brooklyn, NY (US); Kiran Shekar, New York, NY (US); Aaron Berlow, New York, NY (US); Milan Begliarbekov, New York, NY (US)

(73) Assignee: Firehouse Horology, Inc., New York, NY (US)

(21) Appl. No.: 15/365,091

(22) Filed: Nov. 30, 2016

(51) Int. Cl. G04B 17/06; G04B 1/16; C23C 16/06; C23C 16/44; C23C 16/22

(52) U.S. Cl. CPC G04B 17/066; G04B 17/063; C23C 16/44; C23C 16/22; C23C 16/06; G04B 1/165; G04B 1/145

(57) ABSTRACT

This invention teaches a new class of materials that can be used to manufacture hairsprings and/or other components of mechanical watches, and methods for manufacturing these components. The new class of materials is crystalline compounds, including, but not limited to, gallium arsenide, extrinsically doped gallium arsenide, extrinsically doped silicon, gallium nitride, extrinsically doped gallium nitride, gallium phosphide, extrinsically doped gallium phosphide, and quartz. This invention also teaches laminated/coated crystalline compounds. The lamination/coating may be applied by one of the following methods, including but not limited to: plasma enhanced chemical vapor deposition, atomic layer deposition, sputtering, electron beam evaporation, and thermal evaporation. Using crystalline compounds, in particular extrinsically doping the crystalline compounds, affords the possibility to controllably alter the mechanical, electrical, thermal, magnetic, and/or other properties of the watch components. These properties can be further altered by applying single or multiple laminates/coatings of varying thicknesses and/or geometries.

### FIELD OF THE INVENTION

The field of the invention is mechanical timepieces. In particular this invention teaches new classes of materials: crystalline compounds and laminated crystalline compounds that can be used to manufacture hairsprings and other components of mechanical watches. This invention further teaches methods for manufacturing these components.

### BACKGROUND OF THE INVENTION

The timekeeping mechanism of a mechanical watch is referred to as a movement. The movement is comprised of four principal component systems: a barrel with a mainspring, a gear train, an escapement, and a balance with a hairspring. The mainspring is located inside of the barrel and stores energy as it is wound. The gear train transmits energy from the barrel to the escapement, and controls the motion of the watch's hands. The escapement translates rotational motion into lateral impulses that are delivered to the balance. The hairspring causes the balance to oscillate, by providing a restoring force.

The hairspring is one of the components of the watch that is responsible for the watch's precision and accuracy. Accuracy is how close the watch is to displaying the correct time (e.g. does it take exactly a minute for the second hand to travel around once, or does it run fast or slow). Precision is how much one watch varies to the next watch. The hairspring's accuracy is determined by the materials with which it is made and the dimensions of the hairspring. The hairspring's precision depends on the uniformity/tolerance of said materials and dimensions.

Hairsprings have undergone a number of major technical developments to improve their precision.

The first hairsprings for pocket watches, which were manufactured in the late 1600s, were made from metals or simple metallic alloys, i.e., a combination of two or three metals that were alloyed to render the metal more pliable and to regulate the stiffness of the spring. The frequency of these hairsprings were very susceptible to temperature changes and to the effects of magnetic fields.

Later, more sophisticated metal alloys of, for example, iron, chrome, nickel, titanium, beryllium, manganese, and carbon were developed. The precision of the hairsprings formed from alloys is much less adversely affected by the changes in ambient temperature. However, the hairsprings formed from these alloys are still adversely affected by magnetic fields.

An additional undesired feature of the metal alloy hairsprings stems from the nature of the manufacturing process that is used in their creation. The manufacturing process that is used to fashion metal alloy hairsprings consists of an extrusion of the alloy to establish the correct dimensions of the hairspring and then a mechanical coiling process followed by an annealing process. The nature of metal alloys and the processes of extruding and mechanically coiling the hairspring are inherently imprecise. That is the variability of any two hairsprings is greater than the design tolerance. Therefore no two springs oscillate at exactly the same frequency. To address this deficiency, fine adjustments need to be performed during the installation of the metal alloy hairspring.

The most recent development in the manufacturing of hairsprings was the use of semiconductor manufacturing technology, herein referred to as nanofabrication and/or micromachining, and the use of pure silicon to form hairsprings.

Silicon hairsprings can be manufactured using known nanofabrication techniques more accurately, since the nanofabrication process allows the specification of dimensions to sub-micrometer tolerances. An additional advantage of hairsprings formed from silicon stems from the fact that silicon has relatively low magnetic susceptibility. The process of creating silicon wafers, disks of silicon from which the hairsprings are formed, has been designed to reduce the levels of contaminants to a value where the residual impurities no longer give rise to undesirable magnetic effects and are not susceptible to the influence of magnetic fields. Consequently the frequency of hairsprings formed from silicon can be more precisely controlled during the manufacturing process and does not degrade during the lifetime of the spring.

### DISCUSSION OF RELATED ART

Early hairsprings were manufactured from metals and simple metal alloys. Recently silicon was introduced as a material for manufacturing hairsprings. Silicon hairsprings are formed from thin disks of silicon called silicon wafers. The process of manufacturing silicon wafers involves the removal of trace impurities that are regarded as contaminants from the silicon ore. These contaminants are known in the art as dopants. Since it is impossible to remove all of the contaminants from any material, that is no material is 100% pure, the residual contaminants in silicon are referred to as intrinsic dopants in the art.

The present invention teaches a novel and a non-obvious use of crystalline compounds, extrinsically doped crystalline compounds, including extrinsically doped silicon for the hairsprings for mechanical watch movements and methods of manufacture thereof.

Silicon is called intrinsically doped if the concentration of non-silicon atoms in the material is at or below 10¹⁴ atoms per cubic centimeter, which corresponds to a resistivity of approximately 100 ohms or above, depending on the doping atom used. Using higher concentrations of extrinsic dopants will lower the resistivity. Silicon with concentrations of non-silicon atoms above 10¹⁴ atoms per cubic centimeter, such as non-silicon atoms above 10¹⁵ atoms per cubic centimeter, is referred to as extrinsically doped silicon in the art.

A crystalline compound is a crystalline solid where the unit cell is made of more than one type of atom. In prior art, silicon or intrinsically doped silicon has been used. However, extrinsically doped silicon has not been used for the manufacture of hairsprings and/or mechanical watch components. Since the act of creating extrinsically doped silicon modifies a substantial portion of its constituent atoms, it is a crystalline compound, whereas intrinsically doped silicon is a crystalline solid but not a crystalline compound. Therefore it is novel and non-obvious to create a hairspring and/or mechanical watch component from crystalline compounds.

In U.S. Pat. No. 7,077,562 (entitled “Watch hairspring and method for making same”) Bourgeois, et al. teach cutting a hairspring from an intrinsically doped “single-crystal silicon plate.” However, Bourgeois, et al. fail to teach a hairspring formed from crystalline compounds.

In U.S. Pat. No. 8,414,185 (entitled “Mechanical oscillator having an optimized thermoelastic coefficient”) Gygax, et al. teach a mechanical oscillator formed from an intrinsically doped “single-crystal silicon core.” However, Gygax, et al. fail to teach a hairspring formed from crystalline compounds.

In U.S. Pat. No. 8,425,110 (entitled “Breguet overcoil balance spring made of silicon-based material”) Zaugg, et al. teach an overcoil and method of manufacturing using intrinsically doped silicon. However, Zaugg, et al. fail to teach a hairspring formed from crystalline compounds. Zaugg, et al. also fail to teach a hairspring that has been laminated using techniques other than thermal oxidation.

In U.S. Pat. No. 9,004,748 (entitled “Balance spring with two hairsprings and improved isochronism”) Helfer, et al. teach a hairspring “formed from silicon” which is intrinsically doped. However, Heifer, et al. fail to teach a hairspring formed from crystalline compounds.

In U.S. Pat. No. 8,757,868 (entitled “Method of fabricating a timepiece balance spring assembly in micro-machinable material or silicon”) Karapatis, et al. teach a hairspring made with “micro-machinable material or silicon.” However, Karapatis, et al. fail to teach a hairspring formed from crystalline compounds.

In U.S. Pat. No. 8,322,914 (entitled “Silicon overcoil balance spring”) Bifrare, et al. explain an intrinsically doped hairspring “formed in a single silicon part”. However, Bifrare, et al. fail to teach a hairspring formed from crystalline compounds.

In U.S. Pat. No. 8,296,953 (entitled “One-piece hairspring and method of manufacturing the same”) Bühler, et al. teaches an overcoil and method of manufacturing of using intrinsically doped silicon. However, Bühler, et al. fail to teach a hairspring formed from crystalline compounds. Bühler, et al. also fail to teach a hairspring that has been laminated using techniques other than thermal oxidation.

In U.S. Pat. No. 8,393,783 (entitled “Hairspring for a balance wheel/hairspring resonator”) Daout, et al. teach a hairspring formed from intrinsically doped “single-crystal silicon”. However, Daout, et al. fail to teach a hairspring formed from crystalline compounds.

In U.S. Pat. No. 8,562,206 (entitled “Hairspring for timepiece hairspring-balance oscillator, and method of manufacture thereof”) Bossart, et al. teach a hairspring with a special geometry made of a low-density material. However, Bossart et al. fail to teach a hairspring formed from crystalline compounds.

In U.S. Pat. No. 8,348,497 (entitled “Flat balance spring for horological balance and balance wheel/balance spring assembly”) Daout teaches a hairspring of varying coil widths. However, Daout fails to teach a hairspring formed from crystalline compounds.

In U.S. Patent Application 2006/0,055,097 (entitled “Hairspring for balance wheel hairspring resonator and production method thereof”) Conus, et al. teach a hairspring formed from an “amorphous or crystalline material such as a silicon.” However Conus, et al. fail to teach a hairspring formed from crystalline compounds.

In U.S. Pat. No. 8,339,904 (entitled “Reinforced micro-mechanical part”) Rappo, et al. teach a hairspring formed from an “amorphous or crystalline material such as a silicon.” However, Rappo, et al. fail to teach a hairspring formed from crystalline compounds.

In U.S. Pat. No. 9,411,312 (entitled “Silicon overcoil balance spring”) Wang, et al. teach an overcoil and method of manufacturing of using silicon. However, Wang, et al. fail to teach a hairspring formed from crystalline compounds.

In U.S. Pat. No. 8,882,341 (entitled “Stress-relief elastic structure of hairspring collet”) Chu, et al. teach a hairspring formed from a brittle material. However, Chu, et al. fail to teach a hairspring formed from crystalline compounds.

In U.S. Patent Application 2014/0,022,873 (entitled “Hairspring for a time piece and hairspring design for concentricity”) Ching teaches a hairspring formed from “amorphous or crystalline material such as a silicon.” However, Ching fails to teach a hairspring formed from crystalline compounds.

### BRIEF DESCRIPTION OF INVENTION

This invention is a hairspring and/or mechanical timepiece components made from crystalline compounds and a method of manufacture thereof.

In the art of material science, two materials are considered distinct from each other if one or more of their properties, such as thermal properties, mechanical properties, electrical properties, or magnetic properties, are different. In solid materials whose constituent atoms form a periodic arrangement, called a crystalline lattice, these differences in properties arise either from a different arrangement of the constituent atoms of the crystalline lattice, or from different atoms that are arranged in the same type of crystal lattice or both. For example, both graphite and diamond are constituted by carbon atoms; the difference in their physical properties stems from the different arrangement of the carbon atoms in different types of lattices: a “diamond-cubic” lattice in diamond and a planar hexagonal lattice in the case of graphite. Similarly, indium phosphite and gallium arsenide are two different materials; however, the constituent atoms of both of these materials are arranged in the same crystalline lattice, the so called “zincblende lattice.” The different properties of these materials stem from the fact that indium and phosphorus make up the indium phosphide compound whereas gallium and arsenic make up the gallium arsenide compound.

Crystalline compounds are a subclass of crystalline solids, in which the lattice is made up of two or more types of atoms which are arranged in a periodic, hereafter crystalline, structure. The repeating part of the lattice is known in the art as the unit cell. In this patent we teach the use of crystalline compounds for the hairspring of a mechanical timepiece and a method of manufacture thereof.

The preferred embodiments of crystalline compounds used to form the hairspring and/or other mechanical timepiece components include but are not limited to, gallium arsenide, extrinsically doped gallium arsenide, extrinsically doped silicon, and gallium nitride.

Extrinsic doping refers to the intentional addition of dopant atoms. That is, atoms that are different from the atoms that constitute the undoped crystalline lattice. This is accomplished either by ion implantation, by drive-in diffusion, or by other standard techniques well known in the art with the aim of changing the material's physical properties. Since all materials contain a low level of impurities, that is, in practice, there is no material that is 100% pure, the word “extrinsic” is used to differentiate it from materials in which the doping concentration is low. In the latter case, the doping is referred to as “intrinsic doping.” More specifically, in the case of silicon based crystalline compounds, silicon is called intrinsically doped if the concentration of non-silicon atoms in the material is at or below 10¹⁴ atoms per cubic centimeter, which corresponds to a resistivity of approximately 100 ohms or above, depending on the doping atom used. Using higher concentrations of extrinsic dopants will lower the resistivity. Silicon with concentrations of non-silicon atoms above 10¹⁴ atoms per cubic centimeter is referred to as extrinsically doped silicon in the art.

Although pure or intrinsically doped silicon has previously been used in the manufacture of hairsprings, the present invention teaches the use of extrinsic doping of silicon to alter its properties in order to alter the thermal, mechanical, and/or other properties of the hairspring and/or other mechanical timepiece components.

Furthermore, hairsprings and/or mechanical timepiece components formed from crystalline compounds may be formed from a wafer cut in any crystalline orientation, including but not limited to, <111>, <110>, <100>, and/or any other off axis cuts. Selecting the crystalline orientation for the hairspring and/or other mechanical timepiece component allows the user to further control the material's properties.

This patent also teaches that hairsprings and/or mechanical timepiece components formed from crystalline compounds may be formed into a laminate in order to further improve their performance in a mechanical oscillator. A laminate, as defined here, is a material made from two or more constituent components, which when combined, produce a new material with characteristics different from the individual components. The individual components remain separate and distinct within the finished structure. One such example is using two constituents with opposite thermal properties to neutralize effects of temperature on the whole material.

In conventional hairsprings formed from intrinsically doped silicon, a laminate coating of silicon dioxide is sometimes applied to silicon via the process of thermal oxidation in order to alter the thermal properties of the hairspring. Here we teach different methods of applying silicon dioxide, as well as other laminate materials and methods to shape these laminate materials, to attain better control of the thermal, mechanical, and other properties of the resultant hairspring.

### BRIEF DESCRIPTION OF DRAWINGS

FIG. 1 shows a mechanical watch movement without bridges in place.

FIG. 2 shows a hairspring.

FIG. 3 shows the unit cell of the gallium arsenide crystalline compound.

FIG. 4 shows the unit cell of the extrinsically doped silicon crystalline compound.

FIG. 5 shows the effect of germanium doping on the thermal properties of silicon.

FIG. 6 shows the effect of n or p doping of silicon on its mechanical properties.

FIG. 7 shows the unit cell of extrinsically doped gallium arsenide crystalline compound.

FIG. 8 shows the unit cell of the gallium nitride crystalline compound.

FIG. 9a shows an unlaminated crystalline compound wafer.

FIG. 9b shows a wafer that was uniformly laminated on all facets.

FIG. 9c shows a wafer that was uniformly laminated on one facet.

FIG. 9d shows a wafer that has been nonuniformly laminated on all facets.

FIG. 9e shows a wafer that has been nonuniformly laminated on one facet.

FIG. 9f shows a wafer that has been nonuniformly laminated on all facets.

FIG. 10a shows an unstressed wafer.

FIG. 10b shows a wafer that has been stressed by the deposition of a laminate.

FIG. 10c shows a wafer in which the stress caused by the deposition of a laminate was avoided by the deposition of a secondary laminate that was deposited prior to the deposition of the main laminate.

FIG. 11a shows an unstressed wafer.

FIG. 11b shows a wafer that has been stressed by the deposition of a laminate.

FIG. 11c shows a wafer in which the stress caused by the deposition of the laminate has been removed by thermally annealing the wafer.

FIG. 12 shows a schematic representation of the typical temperature variation during an exemplary thermal annealing process used to relieve the stress introduced by lamination.

FIG. 13a shows an atmospheric pressure annealing chamber.

FIG. 13b shows a low pressure/vacuum annealing chamber.

FIG. 13c shows an annealing chamber in which the atmospheric gasses were removed and replaced with different gasses maintained at a desired pressure.

FIG. 14a shows a photograph of a crystalline compound wafer.

FIG. 14b shows a side view of an unpolished crystalline compound wafer.

FIG. 14c shows a side view of a crystalline compound wafer that has been polished on one facet.

FIG. 14d shows a side view of a crystalline compound wafer that has been polished on both facets.

### DETAILED DESCRIPTION OF INVENTION

The movement of a mechanical watch is comprised of four principal systems: a barrel and mainspring which are used for power accumulation and storage, a gear train which is used for power transmission, an escapement which is used to translate motion and deliver power to the balance, and the balance with a hairspring that sets the frequency of the watch. The mainspring is located inside of a toothed barrel. It stores energy as the watch is wound.

The hairspring is typically a spiral spring or any other form of a torsion-spring that provides a restoring force to the balance wheel back towards its neutral or equilibrium position as the balance wheel oscillates. The hairspring typically consists of one or more coils, a collet that is used to attach its center to the balance axle, and a terminal curve that is used to attach the other end of the hairspring to the movement and to perform slight frequency adjustments during the installation of the hairspring into the watch movement.

The frequency of a hairspring, which in turn determines the frequency of the movement, is determined by the elasticity of the material from which the hairspring is formed, the density of the material from which the hairspring is formed, and the dimensions of the hairspring. To a first order approximation the frequency, ω, is given by:

$$ω = √ \overline{\frac{{Ehw}^{3}}{4 {π}^{2} CLI}}$$

where E is the Young's Modulus of the material, h is the height of the hairspring, w is the width of the hairspring's coils, C is the number of coils, L is the total length of the hairspring, and I is the moment of inertia.

Using intrinsically doped silicon, the only parameters that can be changed are the geometric parameters including the height h, width w, number of coils C, and total length L.

The present invention is a hairspring and/or other mechanical timepiece components that is comprised of one or more crystalline compounds, and/or one or more crystalline compounds that contain one or more laminated layers, and/or doped crystalline compounds and/or permutations thereof. Doping the crystalline compounds affords the possibility to alter the elasticity, Young's Modulus, E, density, and moment of inertia, I, thereby giving more options in controlling the hairspring's frequency. Consequently, using crystalline compounds and doped crystalline compounds affords more flexibility in designing the hairspring.

In a first preferred embodiment the gallium arsenide crystalline compound (GaAs) is used to form the hairspring. Gallium arsenide is a crystalline compound comprised of the elements gallium and arsenic. Like silicon and other solid state materials GaAs hairsprings can be formed using conventional nanofabrication techniques. Gallium Arsenide presents several advantages over pure silicon for use in hairsprings for mechanical oscillators. The thermal resistivity of GaAs is 2.27 Kelvin centimeters per Watt, whereas the thermal resistivity for silicon is 0.64 Kelvin centimeters per Watt. Therefore the mechanical properties of resultant hairspring, such as its vibrational frequency, will be less susceptible to changes in ambient temperature due to the greater thermal resistivity of the GaAs crystalline compound. Furthermore, GaAs is a brittle material. This means that the material will deform elastically until it is fractured. The elastic deformation of the material until fracture is a critical for its use in hairsprings since deviations from elasticity cause deviations from isochronism, which adversely affects the precision of the mechanical timepiece.

In another preferred embodiment extrinsically doped silicon is used to form the hairspring. Extrinsically doped silicon is a silicon compound which has been extrinsically doped either by ion implantation or by diffusion or by other means known in the art in order to alter its magnetic, mechanical, electrical, or thermal properties. The possible doping atoms include boron, aluminum, nitrogen, gallium, indium, phosphorus, arsenic, antimony, bismuth, lithium, germanium, oxygen, gold, platinum, and xenon. Due to the nature of the doping process the doping atoms can replace any of the atoms in the unit cell or be intercalated into the unit cell of the silicon compound.

Extrinsically doping silicon enables the controlled alteration of the thermal properties of pure silicon. By doping the silicon with germanium and changing its concentration one can continuously alter the thermal conductivity of silicon from 150 Watts per meter per Kelvin to 22 Watts per meter per Kelvin which corresponds to a tuning range of 680%. Similar results can be achieved by doping silicon with different atoms to different concentrations. Consequently, selecting a particular concentration and type of dopant enables the alteration of the thermal properties of the resultant silicon based crystalline compound. Since the design of a hairspring is constrained by the thermal resistivity of the underlying material, the ability to alter the thermal properties of the material enables greater freedom during the design process.

Furthermore extrinsically doping silicon also allows one to control its mechanical properties. A common way to quantify the mechanical properties of silicon is by measuring three of its stiffness coefficients (also known as elastic coefficients) c11, c12, and c44. These coefficients specify the maximum amount of deformation the material can undergo in a specific direction before breaking. These coefficients can be mathematically related to the Young's modulus of silicon. The Young's modulus is the ratio of stress to strain in a given material and is a typical measure of elasticity in the art. The direction is specified by a particular choice of axes of the unit cell of the crystal. The effect of the dopant concentration and type (n or p) on the elastic coefficients of silicon: c11, c12, and c44 as well as on the temperature dependence of those elastic constants are known in the art and are discussed in detail in Ng, et al., “Temperature Dependence of the Elastic Constants of Doped Silicon,” Department of Mechanical Engineering, Stanford University. The terms p and n doping refer to the role of the dopant as either an electron acceptor or an electron donor respectively. Common p dopants used in the art to form extrinsically doped silicon compounds are boron, aluminum, nitrogen, gallium, and indium. Common “n” dopants (also known as n-type dopants) used in the art to form extrinsically doped silicon compounds are phosphorus, arsenic, antimony, bismuth, and lithium. The dopant concentration of 10¹⁴ atoms per cubic centimeter of these or other dopants corresponds to the intrinsic/background doping commonly found in pure silicon, whereas doping concentrations larger than that result from extrinsic doping.

Najafi and Suzuki showed that strengthening silicon by doping is also possible. Doping silicon to a concentration of 10¹⁹ atoms per cubic centimeter with Boron can increase its fracture strength by 600%.

Doping also allows for the formation of more elastic silicon. Karoui, et al., show that doping silicon with oxygen and/or nitrogen can strengthen silicon by increasing its elastic modulus and hardness. These results show that precisely controlling the concentration of extrinsic dopants during the formation of the extrinsically doped crystalline silicon compound can be used to control the hardness of the silicon and also the thermal resistivity of the elastic/stiffness coefficients. Since the design of a hairspring is constrained by the elasticity of the underlying material, the ability to alter the elasticity of the material enables greater freedom during the design process.

In another preferred embodiment extrinsically doped gallium arsenide is used. Gallium arsenide may be doped with aluminum, indium, tellurium, sulphur, tin, silicon, magnesium, germanium, zinc, or chromium, and other materials known in the art.

Extrinsically doping gallium arsenide affords the same advantages as extrinsically doping silicon. For example Hjort shows that by doping GaAs with aluminum one can alter the Young's modulus of GaAs. The Young's modulus is a ratio of stress to strain in a material, and is a commonly used measure of elasticity in the art. The elasticity coefficients discussed above in the case of extrinsically doped silicon can be mathematically related to the Young's modulus of silicon. Djemel and Castaing further show that doping GaAs with Indium can also strengthen GaAs. Similarly Qi et al show that doping GaAs with magnesium can also alter its mechanical properties. Since the design of a hairspring is constrained by the elasticity of the underlying material, the ability to alter the elasticity of the material enables greater freedom during the design process. Due to nature of the doping process the doping atoms can replace any of the atoms in the unit cell or be intercalated into the unit cell.

Another preferred embodiment a hairspring made from the gallium nitride crystalline compound. Gallium nitride is also a good material for the manufacture of hairsprings for mechanical oscillators since its hardness is 12 gigapascals and fracture toughness is 0.79 megapascals per meter. It is therefore a suitable material for the manufacture of hairsprings.

Lamination is a common technique known in the art in which two or more materials are joined together. A coating is another term in the art that is commonly used to refer to a laminate. For the purposes herein, a coating is defined as part of a laminate in which one material is thin and attached to another material which is thicker. So the thin coating is attached to the thick base.

A conventional lamination technique used in the manufacture of silicon hairsprings is thermal oxidation, in which the hairspring or the material from which the hairspring is formed is heated in an oxygen rich environment to cause the surface of the spring to be oxidized.

While thermal oxidation may be used for the lamination of hairsprings, here we teach that lamination may be achieved using one or more of the following techniques: Plasma Enhanced Chemical Vapor Deposition (PECVD), Atomic Layer Deposition (ALD), Sputtering, Electron Beam Evaporation, or thermal evaporation. Furthermore, the crystalline compounds, discussed in this patent, from which the hairsprings are formed may also be laminated using one or more of the following techniques: Plasma Enhanced Chemical Vapor Deposition (PECVD), Atomic Layer Deposition (ALD), Sputtering, Electron Beam Evaporation, and thermal evaporation.

The use of the above techniques allows a greater deal of freedom to vary the stoichiometry and/or density of coating and/or laminate which in turn affects optical, electrical, mechanical, magnetic, and thermal properties and also behavior of the film (also known as coatings and/or laminates) in subsequent processing steps. These techniques can also be used to vary placement of the laminate. For example, some coatings can be purposefully densified during growth to give a greater selectivity during the subsequent etching process that is used to form the hairspring.

The specific techniques used to produce the laminates and coatings are discussed below.

Plasma Enhanced Chemical Vapor Deposition (PECVD) is a technique that is used to produce coatings, including but not limited to, silicon dioxide, silicon nitride, silicon oxynitride, silicon carbide, and amorphous silicon. This technique offers an improvement over the conventionally employed thermal oxidation used to deposit silicon dioxide coatings on hairsprings. Furthermore dopant gases may be introduced into the gases that create the plasma in PECVD to further alter the properties of the coatings, by either strengthening them or making them more elastic. A discussion of the effects of doping on PECVD films is well known in the art.

It is well known in the art that increasing the power of the radio frequency generator that is used to create a plasma in the PECVD process increases the growth rate, index of refraction, and density of the resultant films.

It is well known in the art that increasing pressure of the gases that comprise the plasma in the PECVD process decreases the index of refraction and density of the resultant films. The relationship between pressure and growth rate can be modeled by a parabolic function. This combination of effects allows one to vary the properties of the coatings independently from each other, such as varying the index of refraction of the film independently from the growth rate.

Similar effects as above can be achieved by altering the partial pressures of the gases which are used to create the plasma for the PECVD process. Typical gases include, but are not limited to, nitrous oxide, oxygen, and silane. For example, increasing the nitrous oxide flow rate, decreases the density of the resultant films.

In the case of silicon nitride films, grown in PECVD, stress can be a major issue, which can cause delamination of the film. It is well known in the art that altering the excitation frequency of the plasma can be used to manage the stress.

It is well known in the art that since PECVD deposits oxides, nitrides, and alternates stacks of oxides and nitrides, including doped oxides and nitride, layers can be easily inserted to mitigate adhesion issues of thicker films.

Atomic Layer Deposition (ALD) is another technique that is used to produce a wide variety of coatings such as, but not limited to, aluminum oxide, hafnium dioxide, zirconium dioxide, yttrium dioxide, tin oxide, aluminum nitride, hafnium nitride, zirconium nitride, yttrium nitride, magnesium nitride or silicon oxynitride, aluminum oxynitride, hafnium oxynitride, zirconium oxynitride, yttrium oxynitride, or magnesium oxynitride. It is well known in the art that ALD produces very dense coatings that are free of pinholes or other microscopic defects. ALD further affords more precise control over the thickness of the laminate. ALD is particularly well suited for the application of adhesion and stress relieving layers as discussed below.

Sputtering is another technique commonly used in the art to apply coatings. Sputtering can be used to apply a wide variety of materials. These materials can be used for adhesion layer, as well as friction reducing layers, as well as for encapsulating and decorative purposes. It is well known in the art that pressure, flow rate of gas, stoichiometry, composition of the target, types of gases, temperature, can be used to alter the properties of the sputtering materials.

Another improvement is a laminate in which one constituent is a crystalline compound and the other constituent is applied conventionally.

Another improvement is a laminate in which one constituent compound is a crystalline compound and the other is a coating applied by one or more of the following techniques: plasma enhanced chemical vapor deposition (PECVD), atomic layer deposition (ALD), electron beam evaporation, thermal evaporation, or sputtering.

Unlike thermal oxidation, which laminates all facets of the wafer (including its sides) the aforementioned techniques enable greater flexibility in the placement of laminations. For example, laminations can be applied uniformly, that is to both the top and bottom facets of the wafer, or non-uniformly, that is to one facet of the wafer. Furthermore, using the above described techniques of PECVD, ALD, sputtering, electron beam evaporation, or thermal evaporation, in conjunction with lithographic patterning, laminations can be applied non-uniformly, that is to only one facet of the wafer. The application of the laminates can be further carried out sequentially in order to laminate a different laminate materials on the top and bottom facets of the wafer or sequentially to alternate the laminate materials applied on different facets of the wafer. Sequential use of lithographic patterning, as is well known in the art, can be further utilized to create patterns of laminates on one or both facets of the wafer. This patterning is carried out by first carrying out a first lithography step, followed by the deposition of a first laminate, then a second lithography step followed by the deposition of the second laminate. The sequence of patterning and laminating steps can thus create patterns of varying degrees of complexity.

Laminating a wafer before or after the hairspring is formed can be used to further improve its mechanical properties, for example the wafer may be strengthened by the application of silicon dioxide, silicon nitride, aluminum oxide, hafnium dioxide, zirconium dioxide, yttrium dioxide, tin oxide, aluminum nitride, hafnium nitride, zirconium nitride, yttrium nitride, magnesium nitride or silicon oxynitride, aluminum oxynitride, hafnium oxynitride, zirconium oxynitride, yttrium oxynitride, or magnesium oxynitride. The application of silicon oxide can also improve the thermal stability of the hairspring.

Furthermore laminate coatings can be applied to change the appearance of the wafer.

Another important reason for lamination is to control stress. Stress of the wafer that is used to form the hairspring can be a result either of the manufacturing process of the wafer or can result from the application of a laminate or a coating. For example, the application of silicon dioxide onto some crystalline compounds can cause stress as a result of the mismatch of the atomic lattice of the crystalline compound onto which the silicon dioxide laminate is applied and the atomic lattice of silicon dioxide. The stress will cause the wafer to develop either a convex or a concave bow, which will alter the mechanical properties of the hairsprings formed therefrom. Therefore, a method for managing stress is essential for the manufacture of hairsprings. In the case where stress is incurred as a result of the laminating/coating process, laminating the wafer with a secondary/intermediate compound, such as aluminum oxide, hafnium dioxide, zinc oxide, zirconium dioxide, yttrium dioxide, tin oxide, aluminum nitride, hafnium nitride, zinc nitride, zirconium nitride, yttrium nitride, magnesium nitride or silicon oxynitride, aluminum oxynitride, hafnium oxynitride, zinc oxynitride, zirconium oxynitride, yttrium oxynitride, or magnesium oxynitride prior to the deposition of the silicon oxide can be used to alleviate the stress.

Another method for managing stress that results from the application of a laminate is controlled annealing of the wafer.

The stress relief mentioned above is accomplished by annealing the laminated wafer for one or more heating and cooling cycles and carefully controlling the temperature during those cycles. One possible annealing process consists of an initial ramp during which the temperature is increased to a desired value in a desired span of time, an initial soak during the course of which the temperature is maintained at a constant value for a desired span of time, a secondary ramp during the course of which the temperature is increased to a desired value in a desired span of time, a secondary soak during the course of which the temperature is maintained at a constant value for a desired span of time, a quench during the course of which the temperature is rapidly decreased to a desired value in a desired span of time, a post quench soak, during the course of which the temperature is maintained at a desired value for a desired span of time, and a final cool down, during the course of which the temperature is decreased back to room temperature in a desired span of time. The exact temperatures and spans of time discussed above have to be experimentally determined for each laminate, or combination of laminates.

The thermal annealing process described above may be carried out either in normal atmosphere or under vacuum or in a gaseous atmosphere in which the gasses typically present in the normal atmosphere have been replaced with different gasses, such as dry nitrogen or forming gas (a nitrogen hydrogen mixture) or any other desired gas or a different gaseous mixture maintained at a desired pressure for the duration of the anneal. Alternatively, the secondary gas may be introduced without first evacuating the chamber and allowed to displace the atmospheric gasses present in the chamber prior to implementing the annealing procedure.

Another improvement of the present invention is the polishing of either one or both facets of the silicon wafer prior to the deposition of the laminate or prior to etching the hairspring. Polishing may be accomplished by either mechanical, chemical, or a combination of chemical and mechanical means. Polishing one or more facets of the wafer improves the adhesion of the laminating layers and improves the thermal transport between the wafer and the etching tool during the etching process. Since the processes used to etch crystalline compounds depend on the temperature of the wafer, maintaining a constant temperature during the etch is crucial for achieving a uniform etch profile. The polishing process may be carried out either on one or both facet of the wafer. Polishing one or both facets of the wafer prior to the subsequent nanofabrication steps improves the yield, reliability, and reproducibility of the process. This, in turn, reduces the variability of the frequencies of the hairsprings that are formed in this process.

In other conceived embodiments, the materials and techniques of using crystalline compounds and/or laminates using crystalline compounds can be used for other mechanical watch components, including, but not limited to: plates, bridges, wheels, pinions, balance, levers, ratchets, other springs, axles, dials, hands, ornamentation, attachment mechanisms, screws, stems, crowns, cases, carriages, hammers, gongs, chains, jewels, and/or gears.

In addition, the aesthetics of the mechanical watch and component parts can be modified using variations on the lamination methods and geometries discussed herein.

### DETAILED DESCRIPTION OF DRAWINGS

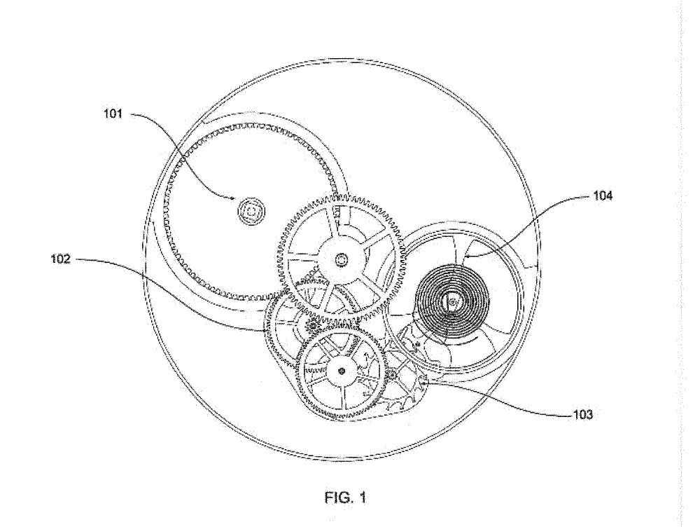

In FIG. 1, a mechanical watch movement is shown without bridges, in order to clearly identify the internal mechanisms. FIG. 1 shows the barrel and mainspring 101 (power accumulator), gear train 102 (transmission), escapement 103 (motion translator) and balance with hairspring 104 (regulator).

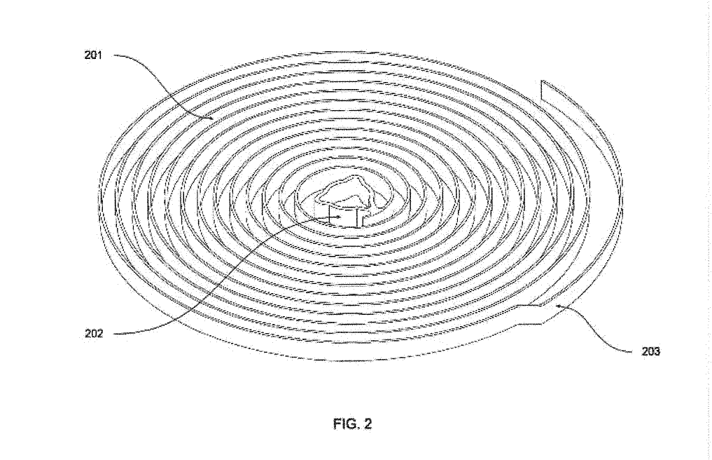

FIG. 2 shows a hairspring for a mechanical oscillator manufactured in one piece from an extrinsically doped crystalline compound. FIG. 2 shows the spring coils 201, collet for attachment to balance staff or the axle, 202 and terminal curve 203.

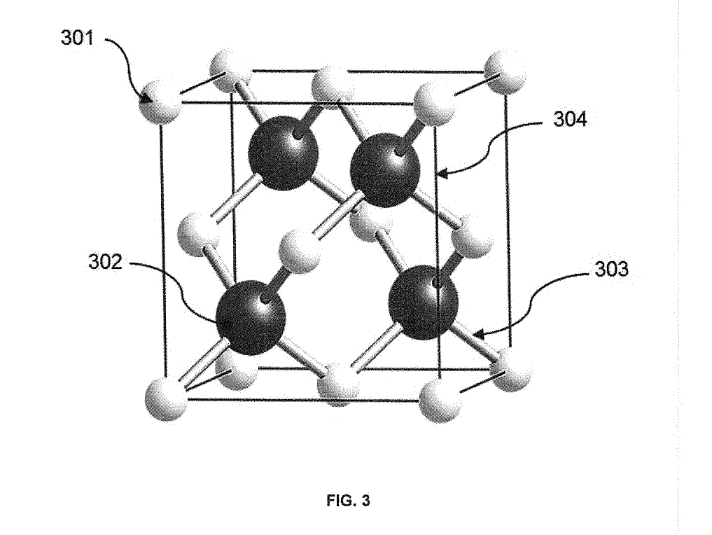

FIG. 3 shows a schematic representation of the gallium arsenide unit cell, the repeating group of atoms that constitute the gallium arsenide compound. FIG. 3 shows the gallium atoms 301 (smaller lighter spheres), the arsenic atoms 302 (larger darker spheres), the chemical bonds joining these atoms 303, and the boundary of the unit cell 304.

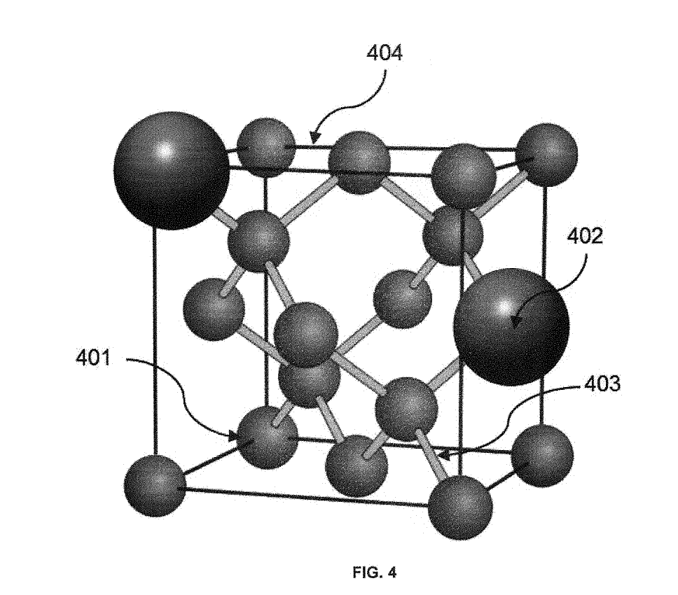

FIG. 4 shows a schematic representation of the extrinsically doped silicon unit cell—the repeating group of atoms that constitute the extrinsically doped silicon compound. FIG. 4 shows the silicon atoms 401 (smaller spheres), the possible locations of the dopant atoms 402 (larger spheres), such as boron, aluminum, nitrogen, gallium, indium, phosphorus, arsenic, antimony, bismuth, lithium, germanium, oxygen, gold, platinum, and xenon, the chemical bonds joining these atoms 403, and the boundary of the unit cell 404.

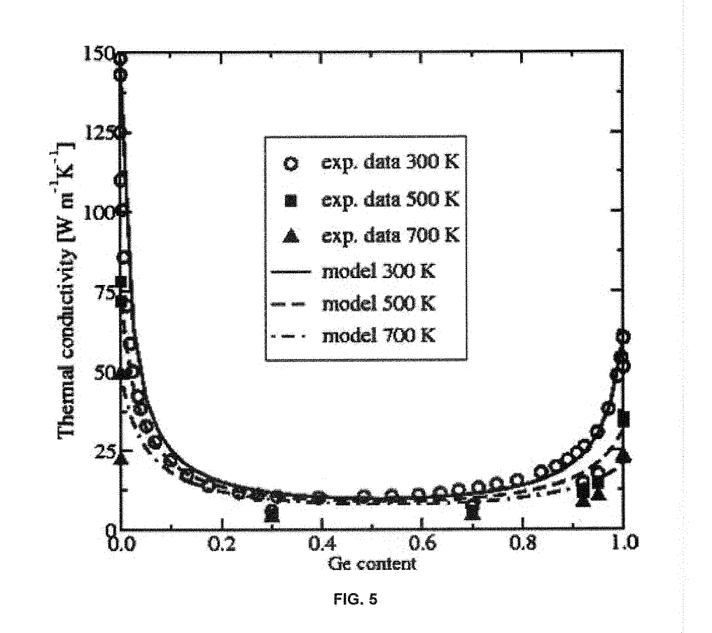

FIG. 5 shows the effect of germanium dopant concentration thermal conductivity of silicon. See WAGNER, MARTIN, Simulation of Thermoelectric Devices, Dissertation, Jul. 9, 1979.

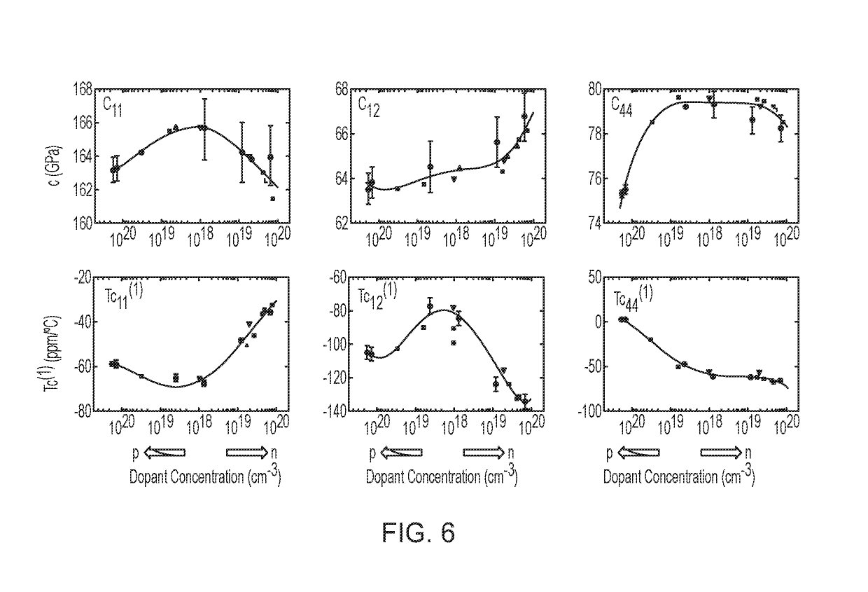

FIG. 6 shows the effect of dopant concentration and type (n or p) on the elastic constants of silicon: c11, c12, and c44 as well as on the temperature dependence of those elastic constants according to Ng, et al., “Temperature Dependence of the Elastic Constants of Doped Silicon,” Department of Mechanical Engineering, Stanford University.

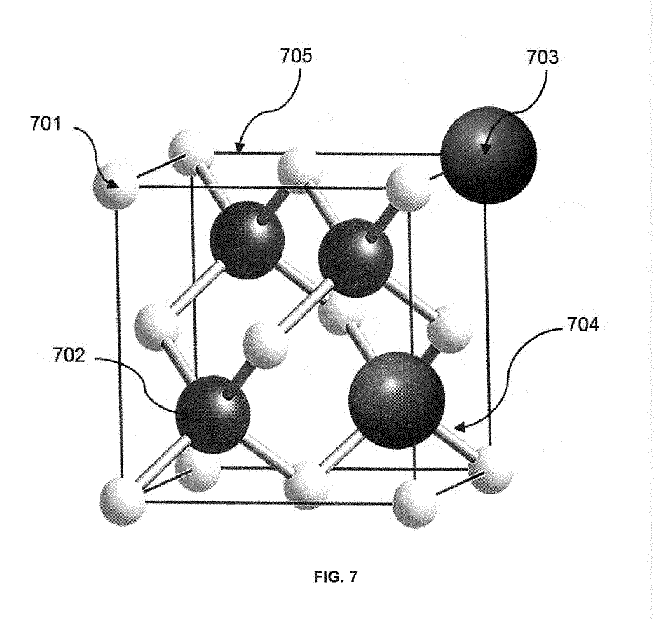

FIG. 7 show a schematic representation of the extrinsically doped gallium arsenide unit cell—the repeating group of atoms that constitute the extrinsically doped gallium arsenide compound. The figure shows the gallium atoms 701 (small light colored spheres), the arsenic atoms 702 (medium sized darker colored spheres), the possible locations of the dopant atoms 703 such as aluminum, indium, tellurium, sulphur, tin, silicon, germanium, zinc, or chromium (large darker colored spheres), the chemical bonds joining these atoms 704, and the boundary of the unit cell 705.

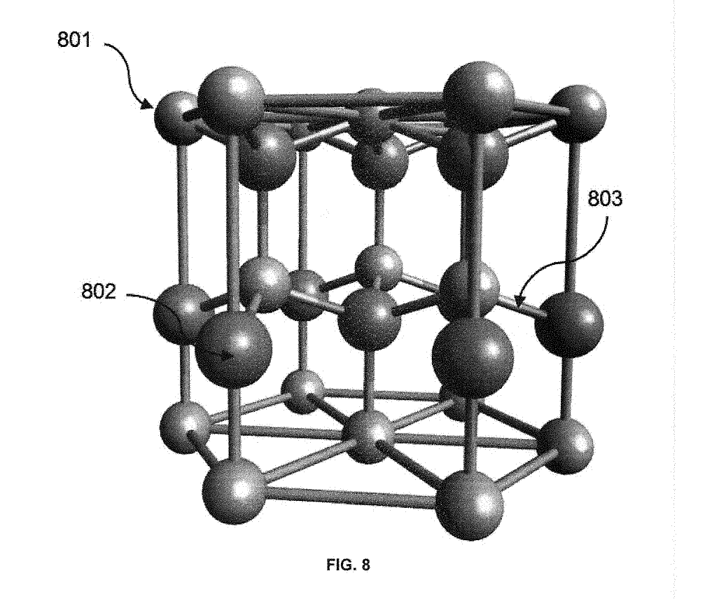

FIG. 8 shows a schematic representation of the gallium nitride unit cell—the repeating group of atoms that constitute the gallium nitride compound. FIG. 8 shows the gallium atoms 801 (smaller spheres), the nitrogen, atoms 802 (larger spheres), and the chemical bonds joining these atoms 803.

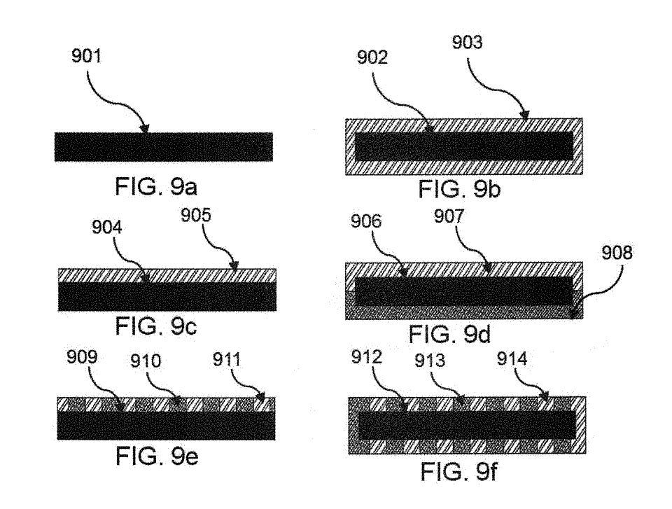

FIG. 9a shows a schematic representation of an unlaminated crystalline compound wafer 901.

FIG. 9b shows a schematic representation of a crystalline compound wafer 902 that has been uniformly laminated on both top and bottom facets 903.

FIG. 9c shows a schematic representation of a crystalline compound wafer 904 that has been laminated on only one facet 905.

FIG. 9d shows a schematic representation of a crystalline compound wafer 906 that has been laminated on the top facet with a laminate 907 and a different laminate 908 on the bottom facet.

FIG. 9e shows a schematic representation of a crystalline compound wafer 909 that has been non-uniformly laminated with the aid of lithographic patterning with a first laminate 910 and a second laminate 911 only on the top facet.

FIG. 9f shows a schematic representation of a crystalline compound wafer 912 that has been non-uniformly laminated with the aid of lithographic patterning with a first laminate 913 and a second laminate 914 on both facets.

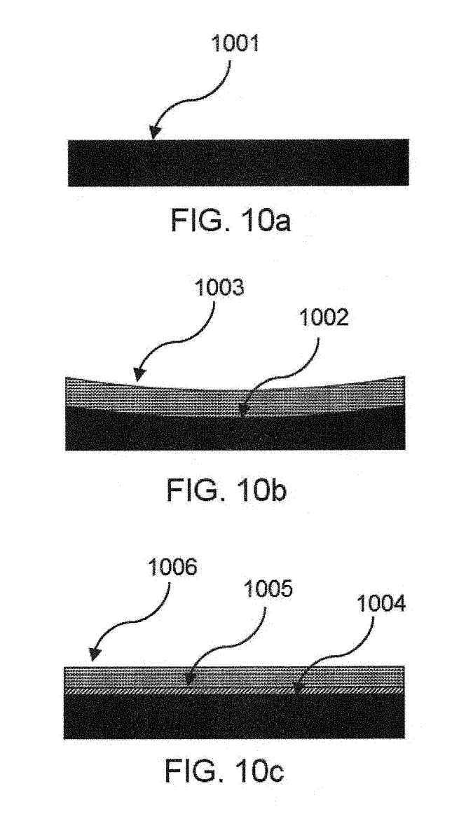

FIG. 10a shows a schematic representation of a crystalline compound wafer prior to lamination 1001.

FIG. 10b shows a schematic representation of a crystalline compound wafer 1002 under stress, as schematically represented by a concave bow in the wafer surface after the deposition of a laminate 1003.

FIG. 10c shows a schematic representation of a crystalline compound wafer 1004 in which the stress was mitigated by the deposition of an intermediate stress relieving laminate, such as aluminum oxide, hafnium dioxide, zinc oxide, zirconium dioxide, yttrium dioxide, titanium oxide, tin oxide, aluminum nitride, hafnium nitride, titanium nitride, tin nitride, zinc nitride, zirconium nitride, yttrium nitride, magnesium nitride or silicon oxynitride, titanium oxynitride, tin oxynitride, aluminum oxynitride, hafnium oxynitride, zinc oxynitride, zirconium oxynitride, yttrium oxynitride, or magnesium oxynitride 1005 prior to the deposition of a secondary laminate 1006.

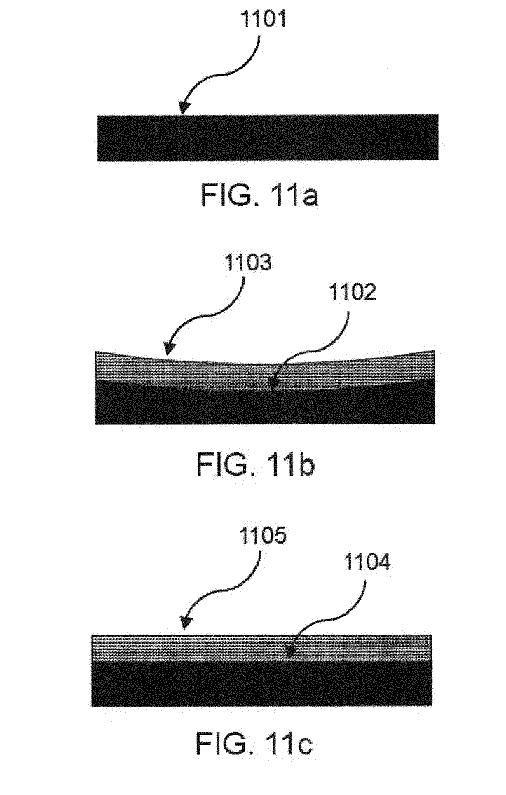

FIG. 11a shows a schematic representation of a crystalline compound wafer prior to lamination 1101.

FIG. 11b shows a schematic representation of a crystalline compound wafer 1102 under stress, as schematically represented by a bow in the wafer surface after the deposition of a laminate 1103.

FIG. 11c shows a schematic representation of a crystalline compound wafer 1104 and a laminate 1105 in which the stress has been removed by thermal annealing the laminated wafer.

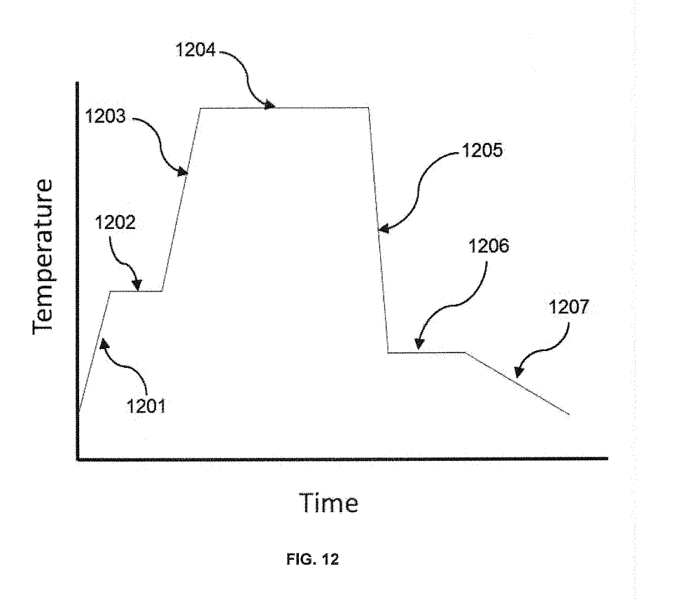

FIG. 12 shows a schematic representation of the typical temperature variation during an exemplary thermal annealing process used to relieve the stress introduced by lamination. The process consists of an initial ramp during which the temperature increased to a desired value in a desired span of time 1201, an initial soak during the course of which the temperature is maintained at a constant value for a desired span of time 1202, a secondary ramp during the course of which the temperature is increased to a desired value in a desired span of time 1203, a secondary soak during the course of which the temperature is maintained at a constant value for a desired span of time 1204, a quench during the course of which the temperature is rapidly decreased to a desired value in a desired span of time 1205, a post quench soak 1206, during the course of which the temperature is maintained at a desired value for a desired span of time, and a final cool down, during the course of which the temperature is decreased back to room temperature in a desired span of time 1207.

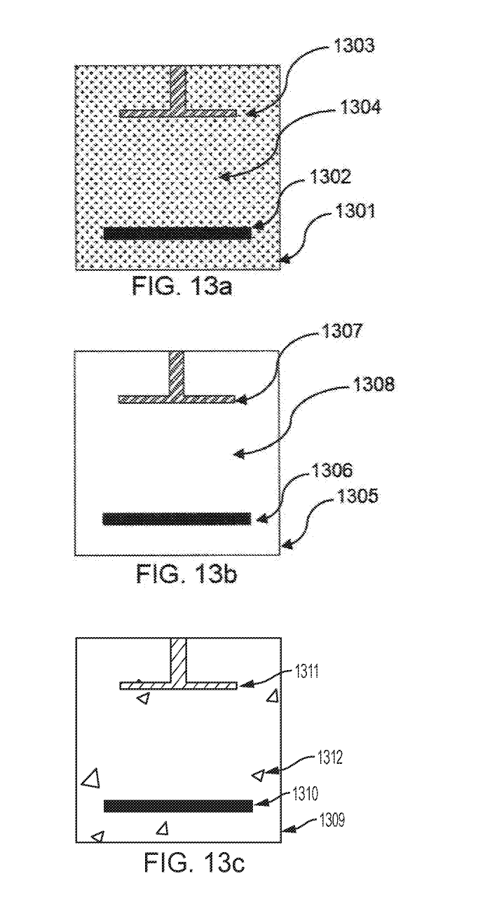

FIG. 13a shows a schematic representation an annealing chamber 1301, with a crystalline compound wafer 1302, a heater 1303, filled with ambient air, i.e., normal atmosphere 1304.

FIG. 13b shows a schematic representation an annealing chamber 1305, with a crystalline compound wafer 1306, a heater 1307 in which the air has been evacuated 1308.

FIG. 13c shows a schematic representation an annealing chamber 1309, with a crystalline compound wafer 1310, a heater 1311 that has been evacuated and subsequently filled with a secondary gas such as dry nitrogen or forming gas (a nitrogen hydrogen mixture) or any other desired gas or gaseous mixture 1312 maintained at a desired pressure. Alternatively, the secondary gas may be introduced without first evacuating the chamber and allowed to displace the atmospheric gases present in the chamber prior to implementing the annealing procedure shown in FIG. 12.

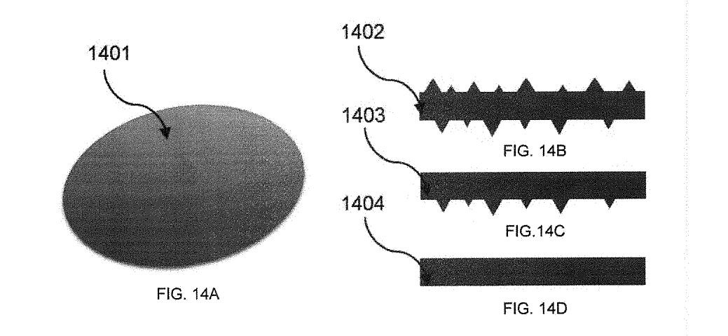

FIG. 14a shows a photograph of an unpolished crystalline compound wafer 1401.

FIG. 14b shows a side view of an unpolished crystalline compound wafer 1402.

FIG. 14b shows a side view of a single side polished crystalline compound wafer 1403.

FIG. 14c shows a side view of a double side polished crystalline compound wafer 1404.

1. A hairspring for a mechanical oscillator for watchmaking wherein the hairspring is made of a crystalline compound such as: gallium arsenide, extrinsically doped gallium arsenide, extrinsically doped silicon, gallium nitride, extrinsically doped gallium nitride, gallium phosphide, extrinsically doped gallium phosphide, and quartz.

2. The hairspring dependent on claim 1, is formed from a wafer, wherein the wafer is cut from any crystalline orientation of an ingot.

3. The hairspring dependent on claim 1 wherein said hairspring has at least one coating for altering the thermal properties of the hairspring.

4. The hairspring dependent on claim 1 wherein said hairspring has at least one coating for altering the mechanical properties of the hairspring.

5. The hairspring dependent on claim 1 wherein said hairspring has at least one coating for altering the aesthetic properties of the hairspring.

6. The hairspring dependent on claim 1, wherein said hairspring has at least one adhesion layer and coating on top of said adhesion layer for altering any properties of the hairspring.

7. The hairspring dependent on claim 1, wherein said hairspring has at least one coating used to mitigate stress that is incurred during the deposition of a second coating.

8. A method of applying a coating to a hairspring of a mechanical oscillator for watchmaking wherein the coating is applied using one of: plasma enhanced chemical vapor deposition (PECVD), atomic layer deposition (ALD), sputtering, electron beam deposition, and thermal evaporation.

9. The method according to claim 8, wherein the stress in the material is mitigated by annealing in a vacuum or gaseous atmosphere.

10. The method according to claim 8 wherein the layer can be silicon oxide, aluminum oxide, hafnium dioxide, zinc oxide, zirconium dioxide, yttrium dioxide, titanium oxide, tin oxide, aluminum nitride, hafnium nitride, titanium nitride, tin nitride, zinc nitride, zirconium nitride, yttrium nitride, magnesium nitride, silicon oxynitride, titanium oxynitride, tin oxynitride, aluminum oxynitride, hafnium oxynitride, zinc oxynitride, zirconium oxynitride, yttrium oxynitride, magnesium oxynitride, diamond-like carbon, amorphous silicon, polycrystalline silicon, hafnium oxide, zirconium oxide, zinc oxide, yttrium oxide, aluminum gallium arsenide, and silicon carbide.

11. The hairspring according to claim 1 wherein the hairspring is made from a double side polished wafer for managing heat or surface roughness of the material.

12. The hairspring according to claim 1 wherein the hairspring is made from a single side polished wafer for managing heat or surface roughness of the material.

13. A spring for measuring mass wherein the spring is made of one of the following: diamond, gallium arsenide, extrinsically doped gallium arsenide, extrinsically doped silicon, gallium nitride, extrinsically doped gallium nitride, gallium phosphide, extrinsically doped gallium phosphide, and quartz.

14. A component for a mechanical watch wherein the component is made of one of the following: diamond, gallium arsenide, extrinsically doped gallium arsenide, extrinsically doped silicon, gallium nitride, extrinsically doped gallium nitride, gallium phosphide, extrinsically doped gallium phosphide, and quartz.

15. The component according to claim 14, wherein the component is a plate.

16. The component according to claim 14, wherein the component is a bridge.

17. The component according to claim 14, wherein the component is a wheel.

18. The component according to claim 14, wherein the component is a jewel.

19. The component according to claim 14, wherein the component is a balance.

20. The component according to claim 14, wherein the component is one of a pinion, levers, ratchets, other springs, axles, dials, hands, ornamentation, attachment mechanisms, screws, stems, crowns, cases, carriages, hammers, gongs, chains, and gears.
